(19) United States
(12) Patent Application Publication
(10) Pub. No.: US 2012/0313221 A1
(43) Pub. Date: Dec. 13, 2012

(54) SEMICONDUCTOR DEVICE AND MANUFACTURING METHOD THEREOF

(75) Inventor: Yoshiaki HIMENO, Yokkaichi-shi (JP)

(73) Assignee: Kabushiki Kaisha Toshiba, Tokyo (JP)

(21) Appl. No.: 13/423,534

(22) Filed: Mar. 19, 2012

(30) Foreign Application Priority Data
Jun. 8, 2011 (JP) 2011-128111

(51) Int. Cl. H01L 29/06; H01L 21/768

(52) U.S. Cl. 257/618; 438/622; 257/E29.005; 257/E21.575

(57) ABSTRACT

In accordance with an embodiment, a semiconductor device includes a substrate, a first insulating film on the substrate, wiring lines including a metal in trenches in the first insulating film, and a second insulating film. The second insulating film covers the first insulating film and the wiring line. The trenches are arranged parallel to one another at predetermined intervals. The dielectric constant of the material of the second insulating film is higher than that of the first insulating film. The lower surface of the second insulating film in a region between the wiring lines locates above a surface that connects the peripheral edges of the upper surfaces of the wiring lines.

### CROSS REFERENCE TO RELATED APPLICATIONS

This application is based upon and claims the benefit of priority from the prior Japanese Patent Application No. 2011-128111, filed on Jun. 8, 2011, the entire contents of which are incorporated herein by reference.

### FIELD

Embodiments described herein relate generally to a semiconductor device and a manufacturing method thereof.

### BACKGROUND

When a bit line is formed above, for example, a memory cell of a semiconductor storage device by using a metal material, a cap material may heretofore be provided over the bit line to prevent contamination.

However, when the cap material is formed by a material of a high dielectric constant, for example, by silicon nitride, the bit line is subject to the high capacitance of the silicon nitride film. If semiconductor devices are further miniaturized in the future, then the speed of wiring signals is significantly delayed, and defective products might be generated, which has been regarded as a problem.

### BRIEF DESCRIPTION OF THE DRAWINGS

FIG. 1 is a plan view showing the general structure of a semiconductor device according to Embodiment 1;

FIG. 2 is a sectional view taken along the line A-A of FIG. 1;

FIG. 3 is a sectional view of a semiconductor device according to Embodiment 2;

FIG. 4A to FIG. 4F are sectional views illustrating a method of manufacturing the semiconductor device according to Embodiment 1; and

FIG. 5 is a sectional view illustrating a method of manufacturing the semiconductor device according to Embodiment 2.

### DETAILED DESCRIPTION

In accordance with an embodiment, a semiconductor device includes a substrate, a first insulating film on the substrate, wiring lines including a metal in trenches in the first insulating film, and a second insulating film. The second insulating film covers the first insulating film and the wiring line.

The trenches are arranged parallel to one another at predetermined intervals. The dielectric constant of the material of the second insulating film is higher than that of the first insulating film. The lower surface of the second insulating film in a region between the wiring lines locates above a surface that connects the peripheral edges of the upper surfaces of the wiring lines.

Embodiments will now be explained with reference to the accompanying drawings. Like components are provided with like reference signs throughout the drawings and repeated descriptions thereof are appropriately omitted. It is to be noted that in the present specification, the term “under” is used to intend that an element is located relatively closer to the rear side of a substrate in a direction perpendicular to the substrate. It is also to be noted that the term “above” is used to intend that an element is located relatively closer to the top side opposite to the rear side in the direction perpendicular to the substrate.

(1) Semiconductor Device

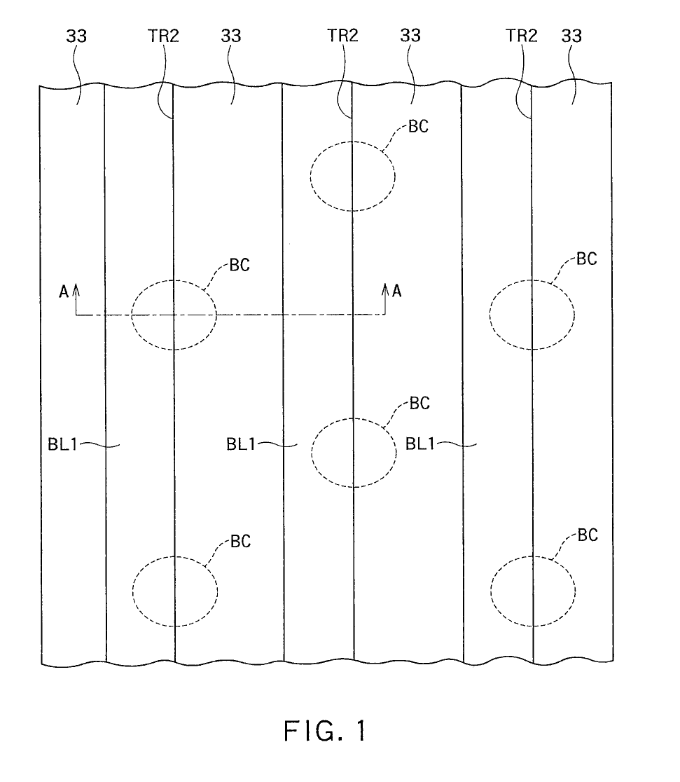

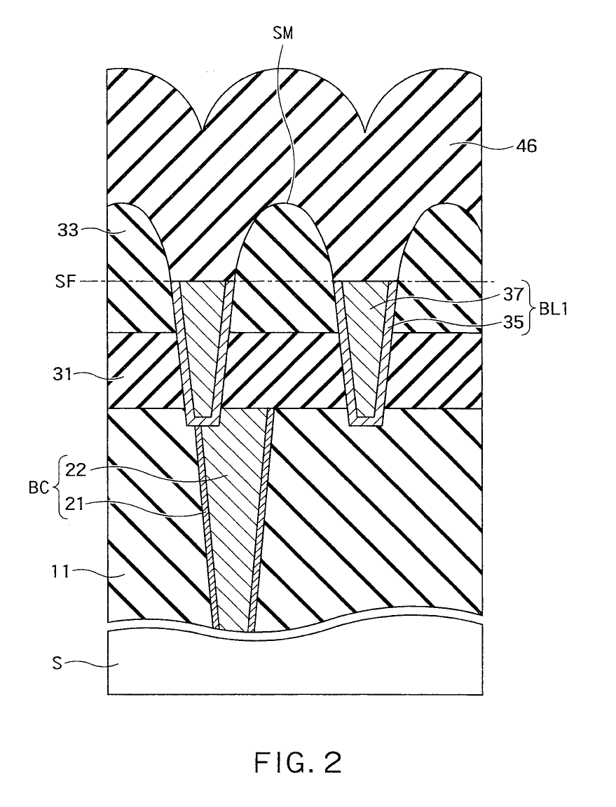

FIG. 1 is a plan view showing the general structure of a semiconductor device according to Embodiment 1. The semiconductor device shown in FIG. 1 includes an oxide film 33 formed on a substrate S (see FIG. 2), a bit line BL1, and a bit line contact BC.

The bit line BL1 is formed by filling trenches TR2 in the oxide film 33 with a metal such as copper (Cu) via a thin metal film such as a titanium (Ti) film. The trenches TR2 are formed parallel to one another at predetermined intervals. In the present embodiment, the bit line BL corresponds to, for example, a wiring line, and the oxide film 33 corresponds to, for example, a first insulating film.

The bit line contact BC is formed under the bit line BL1 so that the bit line contact BC is connected to the bit line BL1. In the present embodiment, an unshown semiconductor element such as a MOS transistor or a flash memory is formed under the bit line BL1, and the bit line BL1 is connected to the semiconductor element.

FIG. 2 shows a sectional view taken along the line A-A which intersects at right angles with the longitudinal direction of the bit line BL1 in FIG. 1. As shown in FIG. 2, the semiconductor device according to the present embodiment further includes a silicon nitride film 46 which is formed over the oxide film 33 and the bit line BL1 each formed on the substrate S. The silicon nitride film 46 functions as a cap layer which prevents the metal to form the bit line BL1 from diffusing and thus causing contamination.

In FIG. 2, a member indicated by the sign 31 is, as will be described later, a silicon nitride film which functions as an etching stopper film during the formation of the trenches TR2. Hereinafter, the silicon nitride film 31 is referred to as a first silicon nitride film, and the silicon nitride film 46 is referred to as a second silicon nitride film. In the present embodiment, the second silicon nitride film 46 corresponds to, for example, a second insulating film. In the plan view of FIG. 1, the second silicon nitride film 46 is not shown.

The semiconductor device according to the present embodiment is characterized in that the oxide film 33 is formed so as to have a step in a region between the adjacent bit lines BL1 and that in accordance with the shape of the oxide film 33, the silicon nitride film 46 is formed in a manner that in the region between the adjacent bit lines BL1 the lower surface of the second silicon nitride film 46 locates above a surface SF that connects the peripheral edges of the upper surfaces of the bit lines BL1. In the sectional shape shown in FIG. 2, the lower surface of the silicon nitride film 46 is arch-shaped in the region between the adjacent bit lines BL1.

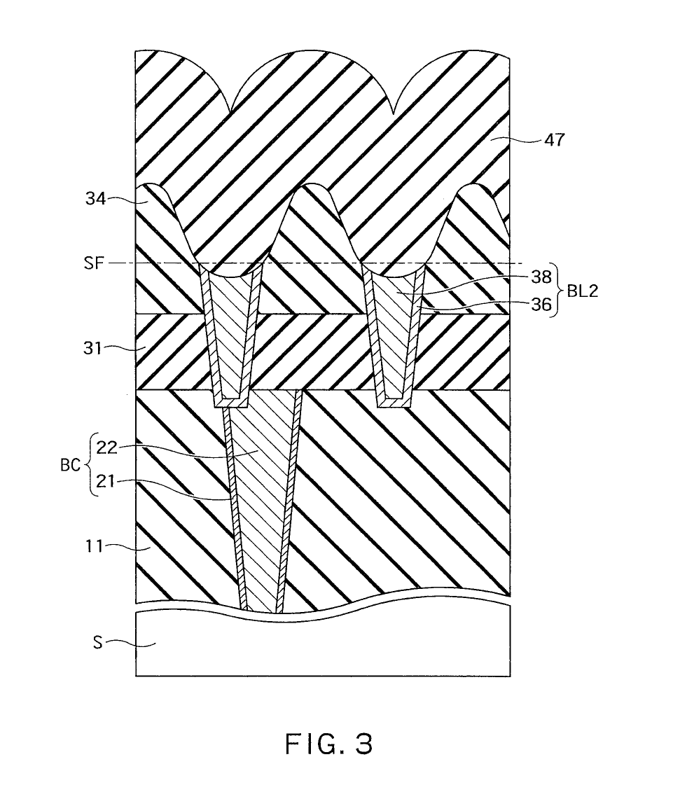

FIG. 3 is a sectional view showing Embodiment 2. A schematic plan view according to Embodiment 2 is similar to FIG. 1. FIG. 3 is a sectional view taken along the line A-A of FIG. 1 in the same manner as the sectional view shown in FIG. 2.

A semiconductor device according to Embodiment 2 is characterized by the shapes of a bit line BL2 and a silicon nitride film 47. Firstly, the upper surface of the bit line BL2 is depressed in its center portion as compared to its peripheral portion. Secondly, an oxide film 34 is substantially inverted-V-shaped in a region between the adjacent bit lines BL in the sectional view shown in FIG. 3, and in accordance with this shape, the lower surface of the second silicon nitride film 47 is also substantially inverted-V-shaped in the region between the adjacent bit lines BL. In the present specification, the term “substantially” is used to cover “rounding” in a contour shape of an element due to a manufacturing process thereof.

Thus, according to semiconductor devices according the first and second embodiments described above, the silicon nitride films 46 and 47 each having a high dielectric constant are formed in a manner that the lower surfaces of the second silicon nitride films 46 and 47 locate above the surface SF that connects the peripheral edges of the upper surfaces of the bit lines BL1 and BL2 in the region between the adjacent bit lines BL1 and BL2. This can prevent the signal speed delay in the bit lines BL1 and BL2. As a result, a highly reliable semiconductor device adaptable to further miniaturization is provided.

(2) Semiconductor Device Manufacturing Methods

The semiconductor devices according to the embodiments described above can be provided by manufacturing methods described below.

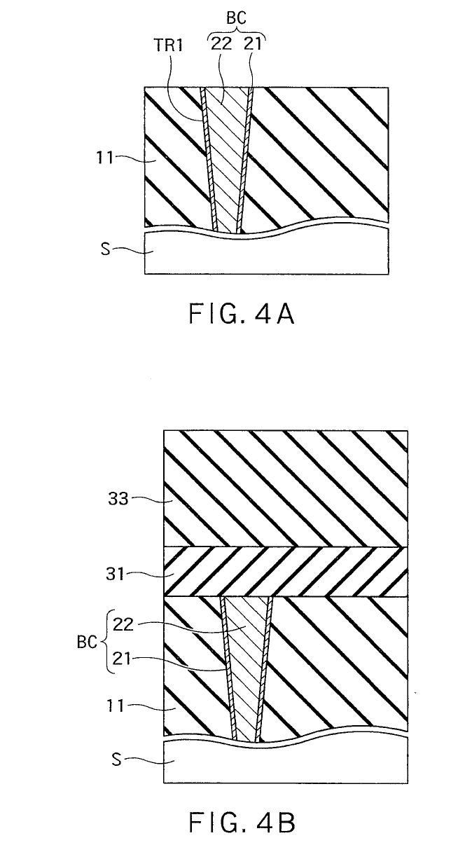

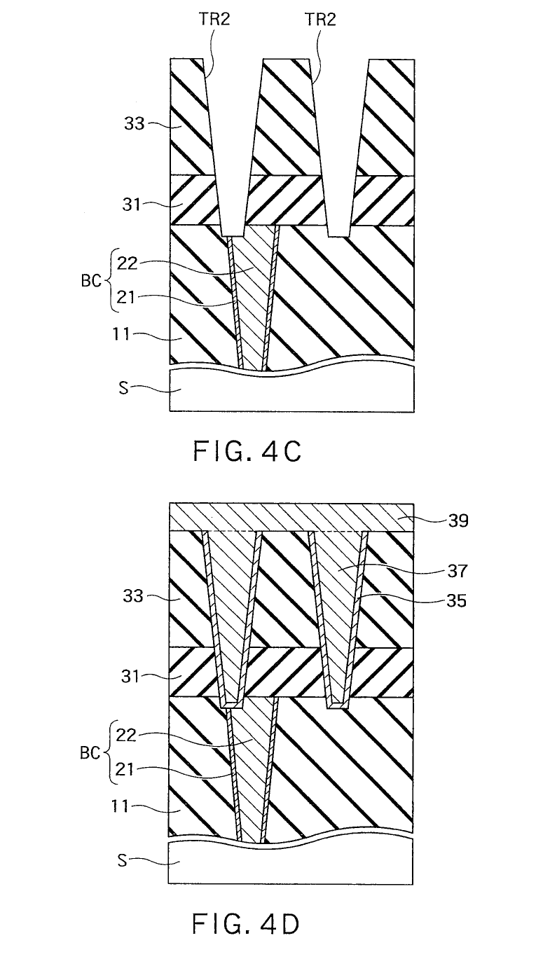

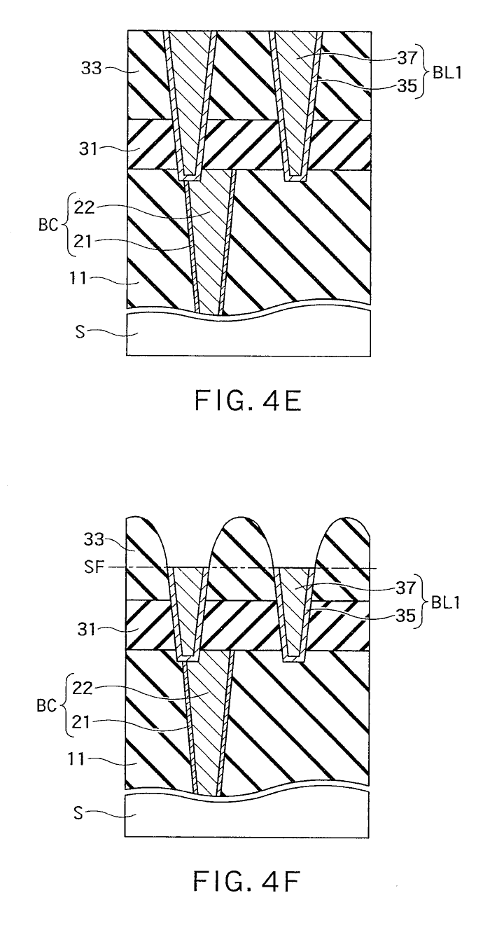

FIG. 4A to FIG. 4F are sectional views illustrating a method of manufacturing the semiconductor device according to Embodiment 1.

First, a silicon oxide film 11 of about 220 nm in thickness is formed on a substrate S by, for example, a plasma chemical vapour deposition (plasma CVD) method. A photoresist (not shown) is fabricated into a desired pattern by a photolithographic technique. This pattern is used as a mask to selectively remove the silicon oxide film 11 by a reactive ion etching (RIE) method, thereby forming a trench pattern TR1 (see FIG. 4A).

The resist mask (not shown) is then removed by O₂ plasma. After a native oxide film is removed by a five-minute choline treatment at 70° C., a titanium nitride (TiN) film 21 of 6 nm in thickness and a tungsten (W) film 22 of 250 nm in thickness are sequentially formed by a physical vapour deposition (PVD) method. Furthermore, the titanium nitride (TiN) film 21 and the tungsten (W) film 22 are removed by a chemical mechanical polishing (CMP) method until the silicon oxide film 11 is exposed. The silicon oxide film 11 is then shaved by about 100 nm and thereby planarized to form a contact plug BC, as shown in FIG. 4A.

As shown in FIG. 4B, a first silicon nitride film 31 of about 20 nm in thickness and a silicon oxide film 33 of 80 nm or more in thickness are sequentially formed by a plasma CVD method.

Then, a photoresist (not shown) is applied, and the photoresist (not shown) is then fabricated into a desired pattern by a photolithographic technique. This pattern is used as a mask to selectively remove the silicon oxide film 33 and the first silicon nitride film 31 by an RIE method. Furthermore, the first silicon nitride film 31 is used as an etching stopper film to shave the silicon oxide film 11 by about 5 nm. The resist is then removed by O₂ plasma, thereby forming trenches TR2, as shown in FIG. 4C.

After a native oxide film on the bit line contact BC is removed by a five-minute choline treatment at 70° C., a Ti film 35 of 8 nm in thickness and a Cu film 37 of 15 nm in thickness are sequentially formed by a PVD method. As shown in FIG. 4D, a Cu film 39 of 450 nm in thickness is then further deposited over the Cu film 37, the Ti film 35, and the oxide film 33 by a plating method, and is heated for 30 minutes in hydrogen-containing nitrogen atmosphere at 150° C., thereby inhibiting the generation of defects in the Cu film.

As shown in FIG. 4E, the Cu films 39 and 37, and the Ti film 35 are removed by a CMP method until the silicon oxide film 33 is exposed. The amount of the removal is set so that the position of the upper surface of the silicon oxide film 33 corresponds to the highest position of the lower surface of the target second silicon nitride film 46 (see the sign SM in FIG. 2) between the bit lines BL.

Then, as shown in FIG. 4F, hydrochloric acid at room temperature or 70° C. is used to set back the Cu film 37 and the Ti film 35 by five-minute etching in accordance with a wet etching with a high selectivity to the silicon oxide film 33, thereby forming a bit line BL1. After this process, the silicon oxide film 33 is, in a region between the bit lines BL1, shaped to have a step rising upward from a surface SF that connects the peripheral edges of the upper surfaces of the bit lines BL1.

The silicon nitride film 46 of about 50 nm in thickness is then deposited over the silicon oxide film 33 and the bit line BL by a plasma CVD method, such that the semiconductor device shown in FIG. 2 is manufactured.

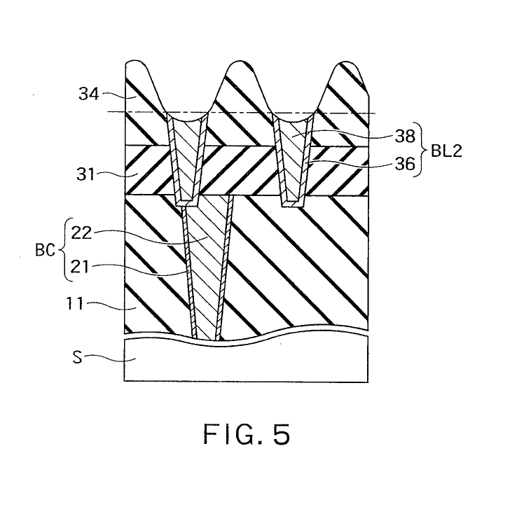

Now, a method of manufacturing the semiconductor device according to Embodiment 2 is described with reference to FIG. 5 in addition to FIG. 4A to FIG. 4E.

The process is similar to that in Embodiment 1 described with reference to FIG. 4A to FIG. 4E from the formation of the bit line contact BC to the formation of the first silicon nitride film 31, the formation of the silicon oxide film 34, a Ti film 36, and a Cu film 38 (see FIG. 5), the formation of an additional Cu film, and up to the removal of this Cu film by a CMP method.

The present embodiment is characterized in that the Cu film 38 and the Ti film 36 are etched and removed by a RIE method under a condition having a high selectivity to the silicon oxide film 34 to set back the Cu film 38 and the Ti film 36. Accordingly, as shown in FIG. 5, the upper surface of the bit line BL2 is depressed in its center portion as compared to its peripheral portion. The side surface of the bit line BL2 is shaped to be steeper than the step of the silicon oxide film 34 in a region between the bit lines BL2, and is substantially inverted-V-shaped in section. Furthermore, a silicon nitride film 47 of about 50 nm in thickness is deposited over the silicon oxide film 34 and the bit line BL2 by a plasma CVD method, such that the semiconductor device shown in FIG. 3 is manufactured.

Thus, according to the semiconductor device manufacturing methods in the first and second embodiments described above, it is possible to manufacture, in a simple process, semiconductor devices which can prevent the signal speed delay in the bit lines BL1 and BL2.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. A semiconductor device comprising:
a substrate;
a first insulating film on the substrate;
wiring lines including a metal in trenches arranged parallel to one another at predetermined intervals in the first insulating film; and
a second insulating film of a material higher in dielectric constant than the first insulating film so as to cover the first insulating film and the wiring line,
wherein the lower surface of the second insulating film in a region between the wiring lines locates above a surface that connects the peripheral edges of the upper surfaces of the wiring lines.

2. The device of claim 1,
wherein the first insulating film has an upward step in the region between the wiring lines.

3. The device of claim 1,
wherein the second insulating film in the region between the wiring lines is arch-shaped in section along a direction intersecting the longitudinal direction of the wiring lines.

4. The device of claim 1,
wherein the upper surfaces of the wiring lines are flush with each other.

5. The device of claim 1,
wherein the upper surface of the wiring line is depressed in its center portion as compared to its peripheral portion.

6. The device of claim 5,
wherein the first insulating film in the region between the wiring lines is substantially inverted-V-shaped in section along a direction intersecting the longitudinal direction of the wiring lines.

7. The device of claim 6,
wherein the second insulating film in the region between the wiring lines is, in accordance with the shape of the first insulating film, substantially inverted-V-shaped in section along the direction intersecting the longitudinal direction of the wiring lines.

8. The device of claim 1,
wherein the wiring line comprises a first metal film on the side surface and bottom surface of the trench, and a second metal film on the first metal film.

9. A semiconductor device manufacturing method comprising:
forming a first insulating film on a substrate;
forming trenches parallel to one another at predetermined intervals in the first insulating film;
filling the trenches with a metal to form wiring lines;
setting back the wiring lines by etching with a condition having a high selectivity to the first insulating film; and
forming a second insulating film covering the first insulating film and the set-back wiring lines using a material higher in dielectric constant than the first insulating film.

10. The method of claim 9,
wherein forming the filling wiring lines comprises eliminating the metal filled in the trenches and the first insulating film until the upper surface of the first insulating film reaches a position corresponding to a position to be highest in the lower surface of the second insulating film.

11. The method of claim 9,
wherein the etching is conducted by a wet etching.

12. The method of claim 11,
wherein forming the wiring lines comprises forming a first metal film on the side surface and bottom surface of the trench, and forming a second metal film on the first metal film.

13. The method of claim 12,
wherein forming the filling wiring lines comprises forming the second metal film so as to cover the first metal film and the first insulating film.

14. The method of claim 9,
wherein the etching is conducted by an RIE method.

15. The method of claim 14, wherein forming the wiring lines comprises forming a first metal film on the side surface and bottom surface of the trench, and forming a second metal film on the first metal film.

16. The method of claim 15, wherein forming the filling wiring lines comprises forming the second metal film so as to cover the first metal film and the first insulating film.
